(19) United States
(12) Patent Application Publication
(10) Pub. No.: US 2015/0155389 A1
(43) Pub. Date: Jun. 4, 2015

(54) METAL OXIDE SEMICONDUCTOR THIN FILM TRANSISTOR

(71) Applicant: CHUNGHWA PICTURE TUBES, LTD., TAOYUAN (TW)

(72) Inventors: Chien-Pang TAI, Taoyuan County (TW); Jun-Yao HUANG, New Taipei City (TW); Yu-Chin PENG, Miaoli County (TW); Ke-Chuan HUANG, New Taipei City (TW)

(73) Assignee: CHUNGHWA PICTURE TUBES, LTD., TAOYUAN (TW)

(21) Appl. No.: 14/133,670

(22) Filed: Dec. 19, 2013

(30) Foreign Application Priority Data
Dec. 2, 2013 (TW) 102222615

(51) Int. Cl. H01L 29/786

(52) U.S. Cl. CPC H01L 29/78606; H01L 29/7869

(57) ABSTRACT

A metal oxide semiconductor thin film transistor includes a source, a drain, a metal oxide semiconductor layer, a gate, a first gate insulating layer and a second gate insulating layer. The metal oxide semiconductor layer is in contact with a portion of the source and a portion of the drain. The first gate insulating layer is interposed between the metal oxide semiconductor layer and the gate and in contact with the gate. The second gate insulating layer is interposed between the metal oxide semiconductor layer and the gate and in contact with the metal oxide semiconductor layer.

### RELATED APPLICATIONS

This application claims priority to Taiwanese Application Serial Number 102222615, filed Dec. 2, 2013, which is herein incorporated by reference.

### BACKGROUND

1. Field of Invention

The present invention relates to a metal oxide semiconductor thin film transistor.

2. Description of Related Art

A liquid crystal display includes a thin film transistor (TFT) substrate, a color filter substrate and a liquid crystal molecule layer disposed therebetween. There are multiple TFTs disposed on the TFT substrate, and each of the TFTs includes a gate, a gate insulating layer, a semiconductor layer, a source and a drain. The semiconductor layer may be made of a material including amorphous silicon, polycrystalline silicon, microcrystalline silicon, monocrystalline silicon, organic semiconductors, metal oxide semiconductors or other suitable materials.

Compared with the amorphous silicon TFT, the metal oxide semiconductor TFT possesses higher carrier mobility and thus exhibits better electrical performance. However, the metal oxide semiconductor layer is very sensitive to hydrogen and oxygen atoms. The metal oxide semiconductor layer may be deteriorated since hydrogen or oxygen atoms go thereinto, resulting in poor electrical performance. The metal oxide semiconductor layer may even becomes to a conductor due to the presence of hydrogen atoms, which results in the metal oxide semiconductor TFT cannot be operated.

Therefore, an insulating layer should be formed in an environment with extremely low hydrogen and oxygen contents so as not to affect electrical performance of the metal oxide semiconductor layer. Nevertheless, it requires a very long time to form the insulating layer with a certain thickness under an environment of extremely low hydrogen and oxygen contents, such that the machine may easily become unstable and abnormalities. In view of the above, there is a need for an improved metal oxide semiconductor TFT to solve the aforementioned problems.

### SUMMARY

An aspect of the present invention provides a metal oxide semiconductor thin film transistor (TFT) including a source, a drain, a metal oxide semiconductor layer, a gate, a first gate insulating layer and a second gate insulating layer. The metal oxide semiconductor layer is in contact with a portion of the source and a portion of the drain. The first gate insulating layer is interposed between the metal oxide semiconductor layer and the gate and in contact with the gate. The second gate insulating layer is interposed between the metal oxide semiconductor layer and the gate and in contact with the metal oxide semiconductor layer.

According to one embodiment of the present invention, the first gate insulating layer has a thickness greater than a thickness of the second gate insulating layer.

According to one embodiment of the present invention, the first gate insulating layer and the second gate insulating layer are disposed beneath the metal oxide semiconductor layer, and the first gate insulating layer covers the gate, and the second gate insulating layer is interposed between the first gate insulating layer and the metal oxide semiconductor layer.

According to one embodiment of the present invention, the metal oxide semiconductor TFT further includes a first protective layer covering and in contact with the metal oxide semiconductor layer.

According to one embodiment of the present invention, the first protective layer has two openings, and the metal oxide semiconductor layer is in contact with the portion of the source and the portion of the drain through the two openings.

According to one embodiment of the present invention, the metal oxide semiconductor layer is fully covered by the second gate insulating layer, the first protective layer, the source and the drain.

According to one embodiment of the present invention, the metal oxide semiconductor TFT further includes a second protective layer covering the first protective layer.

According to one embodiment of the present invention, the second protective layer has a thickness greater than a thickness of the first protective layer.

According to one embodiment of the present invention, the first gate insulating layer and the second gate insulating layer are disposed above the metal oxide semiconductor layer, and the second gate insulating layer covers the metal oxide semiconductor layer, and the first gate insulating layer is interposed between the second gate insulating layer and the gate.

According to one embodiment of the present invention, the metal oxide semiconductor layer is not in contact with the first gate insulating layer.

### BRIEF DESCRIPTION OF THE DRAWINGS

The invention can be more fully understood by reading the following detailed description of the embodiment, with reference made to the accompanying drawings as follows:

FIG. 1 is a cross-sectional view of a bottom gate type metal oxide semiconductor thin film transistor (TFT) according to one embodiment of the present invention;

FIG. 2 is a cross-sectional view of a bottom gate type metal oxide semiconductor TFT according to one embodiment of the present invention;

FIG. 3 is a cross-sectional view of a bottom gate type metal oxide semiconductor TFT according to one embodiment of the present invention;

FIG. 4 is a cross-sectional view of a top gate type metal oxide semiconductor TFT according to one embodiment of the present invention; and

FIG. 5 is a cross-sectional view of a top gate type metal oxide semiconductor TFT according to one embodiment of the present invention.

### DETAILED DESCRIPTION

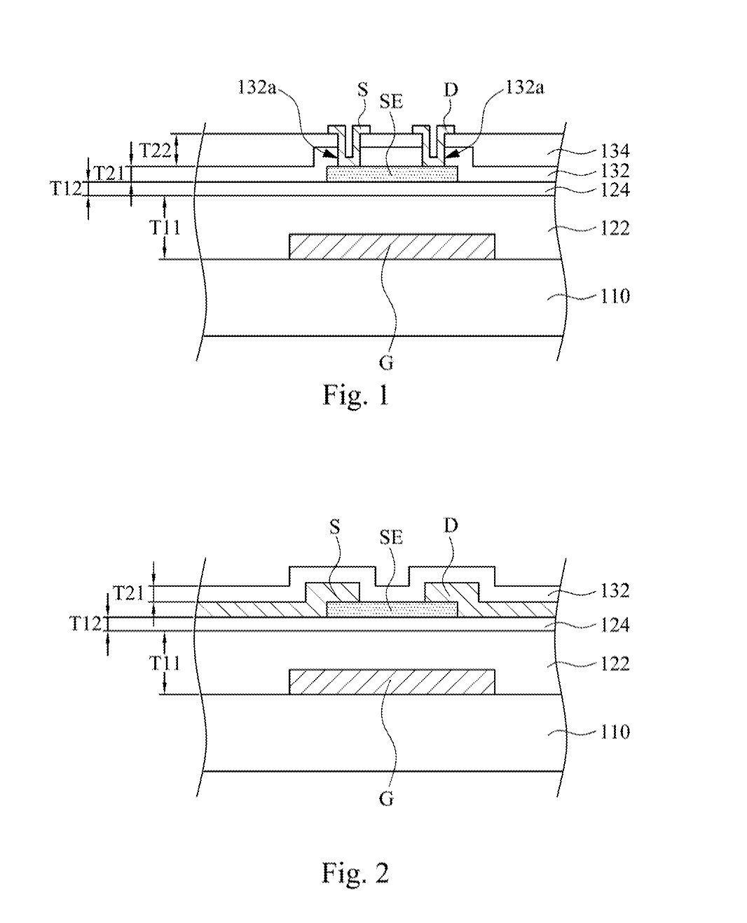

An aspect of the present invention provides a metal oxide semiconductor thin film transistor (TFT). FIG. 1 is a cross-sectional view of a bottom gate type metal oxide semiconductor TFT according to one embodiment of the present invention. As shown in FIG. 1, the metal oxide semiconductor TFT includes a source S, a drain D, a metal oxide semiconductor layer SE, a gate G, a first gate insulating layer 122 and a second gate insulating layer 124.

The metal oxide semiconductor TFT may be disposed on a substrate 110. The substrate 110 may be glass, quartz or transparent polymer materials. The gate G may be made of a metal or an alloy, such as molybdenum (Mo), chromium (Cr), aluminum (Al), neodymium (Nd), titanium (Ti), copper (Cu), silver (Ag), gold (Au), zinc (Zn), indium (In), gallium (Ga), other suitable metals or a combination thereof. For example, a metal layer (not shown) may be formed by sputtering, evaporation or other thin film deposition techniques, and the metal layer is then patterned by photolithographic and etching processes to form the gate G.

For the bottom gate type metal oxide semiconductor TFT, the first gate insulating layer 122 and the second gate insulating layer 124 are disposed beneath the metal oxide semiconductor layer SE. The first gate insulating layer 122 covers the gate G. Specifically, the first gate insulating layer 122 is interposed between the metal oxide semiconductor layer SE and the gate G and in contact with the gate G. The first gate insulating layer 122 may be made of an inorganic dielectric material, such as silicon oxide, silicon nitride, silicon oxynitride or a combination thereof. The first gate insulating layer 122 may be formed by a chemical vapor deposition (CVD) method or other suitable thin film deposition techniques.

The second gate insulating layer 124 is interposed between the metal oxide semiconductor layer SE and the gate G and in contact with the metal oxide semiconductor layer SE. Specifically, the second gate insulating layer 124 is interposed between the first gate insulating layer 122 and the metal oxide semiconductor layer SE. The second gate insulating layer 124 may also be made of an inorganic dielectric material, such as silicon oxide, silicon nitride, silicon oxynitride or a combination thereof. The second gate insulating layer 124 should be formed in an environment with extremely low hydrogen and oxygen contents (e.g., by a CVD process) since it should be in contact with the metal oxide semiconductor layer SE, and thus a formation rate of the second gate insulating layer 124 is very slow. In one embodiment, hydrogen content (e.g., derived from silicon hydride (SiH₄)) for forming the second gate insulating layer 124 is lower than or equal to 100 ppm, and oxygen content (e.g., derived from nitrous oxide (N₂O)) is lower than or equal to 2800 ppm; hydrogen content for forming the first gate insulating layer 122 may be greater than 100 ppm, and oxygen content may be greater than 2800 ppm, and thus a formation rate of the first gate insulating layer 122 is higher. In one example of the embodiment, hydrogen content for forming the second gate insulating layer 124 is in a range of 80-100 ppm, and oxygen content is in a range of 2600-2800 ppm, and a formation rate is about 10 Å/s; hydrogen content for forming the first gate insulating layer 122 is in a range of 400-600 ppm, and oxygen content is in a range of 5900-6100 ppm, and a formation rate is about 50 Å/s. A process time is shortened because the first gate insulating layer 122 can be formed quickly. In order to further shorten the process time, the second gate insulating layer 124 with a thinner thickness may be formed. Therefore, in one embodiment, the first gate insulating layer 122 has a thickness T11 greater than a thickness T12 of the second gate insulating layer 124.

The metal oxide semiconductor layer SE is in contact with a portion of the source S and a portion of the drain D. The metal oxide semiconductor layer SE may be made of zinc oxide (ZnO), zinc tin oxide (ZnSnO), cadmium tin oxide (CdSnO), gallium tin oxide (GaSnO), titanium tin oxide (TiSnO), indium gallium zinc oxide (InGaZnO), indium zinc oxide (InZnO), copper aluminum oxide (CuAlO), strontium copper oxide (SrCuO), lanthanum copper oxychalcogenide (LaCuOS), other suitable materials or a combination thereof. For example, a metal oxide semiconductor material layer (not shown) is formed by a sputtering process, and photolithographic and etching processes are then performed to form the metal oxide semiconductor layer SE.

The metal oxide semiconductor TFT further includes a first protective layer 132 covering and in contact with the metal oxide semiconductor layer SE. The first protective layer 132 should be formed under an environment of extremely low hydrogen and oxygen contents since it should be in contact with the metal oxide semiconductor layer SE. Accordingly, the materials and the processes suitable for the second gate insulating layer 124 can also be applied for the first protective layer 132. That is, the first protective layer 132 may also be made of an inorganic dielectric material, such as silicon oxide, silicon nitride, silicon oxynitride or a combination thereof. In one embodiment, hydrogen content for forming the first protective layer 132 is lower than or equal to 100 ppm, and oxygen content is lower than or equal to 2800 ppm. In order to let the source S and the drain D in contact with the metal oxide semiconductor layer SE, the first protective layer 132 may have two openings 132a, and thus the metal oxide semiconductor layer SE may be in contact with the portion of the source S and the portion of the drain D through the two openings 132a.

In the embodiment of FIG. 1, the metal oxide semiconductor TFT further includes a second protective layer 134 covering the first protective layer 132. The tolerance of hydrogen and oxygen contents in the process for forming the second protective layer 134 is higher in that the second protective layer 134 is not in contact with the metal oxide semiconductor layer SE. In one embodiment, hydrogen content for forming the second protective layer 134 is greater than 100 ppm, and oxygen content is greater than 2800 ppm. For one example, hydrogen content for forming the second protective layer 134 is in a range of 400-600 ppm, and oxygen content is in a range of 5900-6100 ppm, and a formation rate is about 50 Å/s. Further, the process time can be saved by forming the first protective layer 132 with a thinner thickness. Therefore, in one embodiment, the second protective layer 134 has a thickness T22 greater than a thickness T21 of the first protective layer 132.

The source S and the drain D are disposed in the two openings 132a of the first protective layer 132. The materials of the source S and the drain D can be referred to those exemplified for the gate G. For instance, a metal layer (not shown) may be formed by sputtering, evaporation or other thin film deposition techniques, and then patterned by photolithographic and etching processes to form the source S and the drain D. It is noteworthy that the metal oxide semiconductor layer SE is fully covered by the second gate insulating layer 124, the first protective layer 132, the source S and the drain D, and not in contact with the first gate insulating layer 122 and the second protective layer 134, such that the metal oxide semiconductor layer SE cannot be affected by the compositions of the first gate insulating layer 122 and the second protective layer 134.

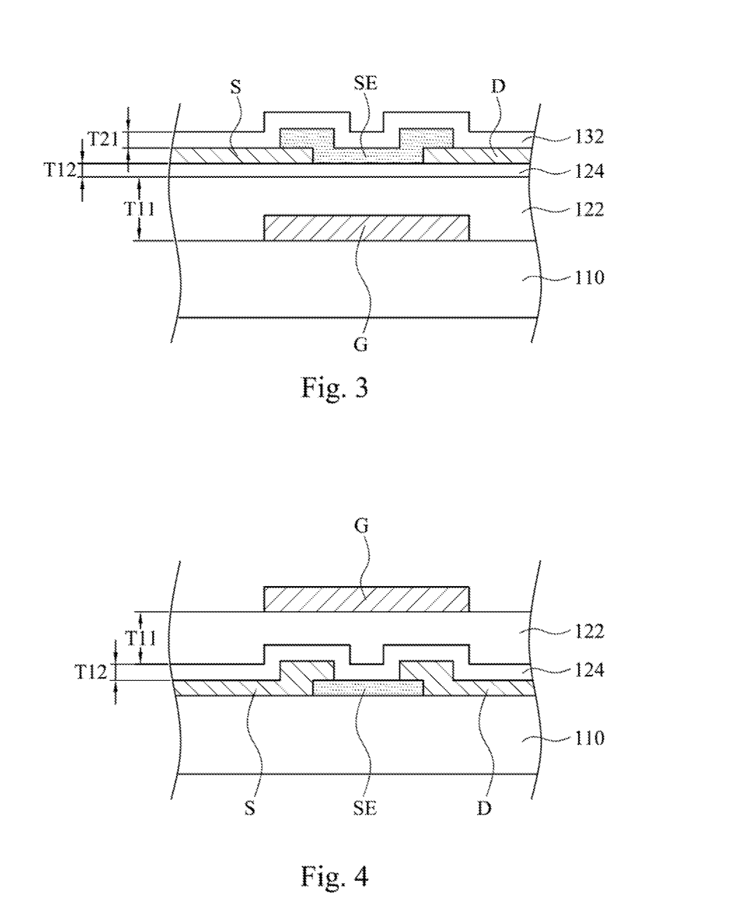

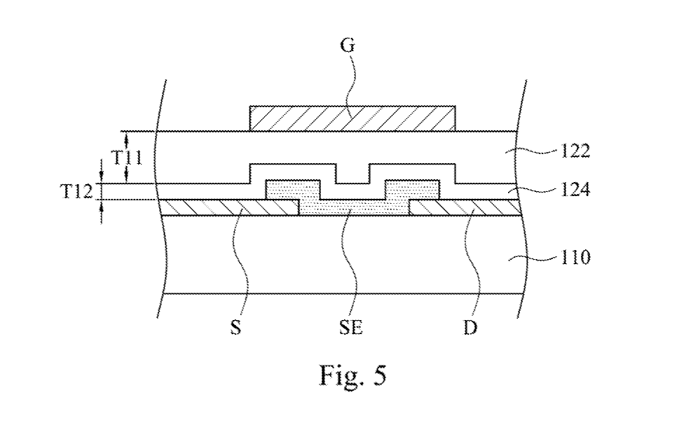

Other embodiments of the present invention are provided below. FIGS. 2-3 are cross-sectional views of bottom gate type metal oxide semiconductor TFTs. FIGS. 4-5 are cross-sectional views of top gate type metal oxide semiconductor TFTs. Embodiments (e.g., the materials and the manufacturing methods) of each element of FIGS. 2-5 can be referred to those exemplified for an element with a same name of FIG. 1.

Referring to FIG. 2, the structure composed of the substrate 110, the gate G, the first gate insulating layer 122 and the second gate insulating layer 124 of FIG. 2 is the same as that of FIG. 1. The difference between FIGS. 1-2 is that the source S and the drain D of FIG. 2 are directly formed on the metal oxide semiconductor layer SE, and those of FIG. 1 are in contact with the metal oxide semiconductor layer SE through the two openings 132a.

Referring to FIG. 3, the structure composed of the substrate 110, the gate G, the first gate insulating layer 122 and the second gate insulating layer 124 of FIG. 3 is the same as that of FIG. 1. The difference between FIGS. 1 and 3 is that in FIG. 3, the source S and the drain D are formed, and the metal oxide semiconductor layer SE is then formed; in FIG. 1, the metal oxide semiconductor layer SE is formed, and the source S and the drain D are then formed.

Referring to FIG. 4, the metal oxide semiconductor TFT includes a source S, a drain D, a metal oxide semiconductor layer SE, a gate G, a first gate insulating layer 122 and a second gate insulating layer 124. The metal oxide semiconductor layer SE is in contact with a portion of the source S and a portion of the drain D. The first gate insulating layer 122 is interposed between the metal oxide semiconductor layer SE and the gate G and in contact with the gate G. The second gate insulating layer 124 is interposed between the metal oxide semiconductor layer SE and the gate G and in contact with the metal oxide semiconductor layer SE.

For the top gate type metal oxide semiconductor TFT, the first gate insulating layer 122 and the second gate insulating layer 124 are disposed above the metal oxide semiconductor layer SE, and the second gate insulating layer 124 covers the metal oxide semiconductor layer SE, and the first gate insulating layer 122 is interposed between the second gate insulating layer 124 and the gate G. The metal oxide semiconductor layer SE is fully covered by the substrate 110, the second gate insulating layer 124, the source S and the drain D, and not in contact with the first gate insulating layer 122, such that the metal oxide semiconductor layer SE cannot be affected by the composition of the first gate insulating layer 122.

Referring to FIG. 5, an arrangement of the substrate 110, the second gate insulating layer 124, the first gate insulating layer 122 and the gate G of FIG. 5 is the same as that of FIG. 4. The difference between FIGS. 4-5 is that in FIG. 5, the source S and the drain D are formed, and the metal oxide semiconductor layer SE is then formed; in FIG. 4, the metal oxide semiconductor layer SE is formed, and the source S and the drain D are then formed.

As mentioned above, it can be understood that the metal oxide semiconductor layer SE is in contact with high-quality inorganic dielectric materials (e.g., the second gate insulating layer 124 of FIGS. 1-5 and the first protective layer 132 of FIGS. 1-3) to eliminate influences on electric performance of the metal oxide semiconductor layer SE. Other insulating layers (e.g., the first gate insulating layer 122 of FIGS. 1-5 and the second protective layer 134 of FIG. 1) may be formed under an environment of higher hydrogen and oxygen contents to significantly shorten process time and avoid abnormalities in the machine, and thus to solve the problems faced in the technical art.

1. A metal oxide semiconductor thin film transistor, comprising:
a source and a drain;
a metal oxide semiconductor layer in contact with a portion of the source and a portion of the drain;
a gate;
a first gate insulating layer made of silicon oxide, beneath the metal oxide semiconductor layer and interposed between the metal oxide semiconductor layer and the gate and in contact with the gate; and
a second gate insulating layer made of silicon oxide, interposed between the metal oxide semiconductor layer and the first gate insulating layer and in contact with the metal oxide semiconductor layer, wherein a formation rate of the first gate insulating layer is higher than a formation rate of the second gate insulating layer.

2. The metal oxide semiconductor thin film transistor of claim 1,
wherein the first gate insulating layer has a thickness greater than a thickness of the second gate insulating layer.

3. The metal oxide semiconductor thin film transistor of claim 1, wherein the first gate insulating layer covers the gate.

4. The metal oxide semiconductor thin film transistor of claim 1, further comprising a first protective layer covering and in contact with the metal oxide semiconductor layer.

5. The metal oxide semiconductor thin film transistor of claim 4, wherein the first protective layer has two openings, and the metal oxide semiconductor layer is in contact with the portion of the source and the portion of the drain through the two openings.

6. The metal oxide semiconductor thin film transistor of claim 4, wherein the metal oxide semiconductor layer is fully covered by the second gate insulating layer, the first protective layer, the source and the drain.

7. The metal oxide semiconductor thin film transistor of claim 4, further comprising a second protective layer covering the first protective layer.

8. The metal oxide semiconductor thin film transistor of claim 7, wherein the second protective layer has a thickness greater than a thickness of the first protective layer.

9. The metal oxide semiconductor thin film transistor of claim 1, wherein the first gate insulating layer and the second gate insulating layer are disposed above the metal oxide semiconductor layer, and the second gate insulating layer covers the metal oxide semiconductor layer, and the first gate insulating layer is interposed between the second gate insulating layer and the gate.

10. The metal oxide semiconductor thin film transistor of claim 1, wherein the metal oxide semiconductor layer is not in contact with the first gate insulating layer.
